(19) United States
(12) Patent Application Publication
(10) Pub. No.: US 2026/0187784 A1
(43) Pub. Date: Jul. 2, 2026

(54) TOOL-SPECIFIC MACHINE LEARNING SOLUTIONS FOR SEMICONDUCTOR EXAMINATION

(71) Applicant: Applied Materials Israel Ltd., Rehovot (IL)

(72) Inventors: Ran YACOBY, Jerusalem (IL); Boris LEVANT, Rehovot (IL); Naom TEOMIM, Rehovot (IL); Bar DUBOVSKI, Beit Hashmonay (IL); Nir BILLFELD, Kiryat Ata (IL); Anna LEVANT, Rehovot (IL); Boaz COHEN, Lehavim (IL)

(21) Appl. No.: 19/005,733

(22) Filed: Dec. 30, 2024

(51) Int. Cl. G06T 7/00; G01N 23/2251; G06F 30/31; G06T 11/00

(52) U.S. Cl. CPC G06T 7/001; G06F 30/31; G06T 11/00; G01N 23/2251; G01N 2223/6116; G06T 2207/10061; G06T 2207/20081; G06T 2207/30148

(57) ABSTRACT

The presently disclosed subject matter includes a computer system and a computer-implemented method dedicated to utilizing a machine learning model trained to generate synthetic examination output images that reflect variations in tool configurations. By incorporating different priors related to operational parameters during inference, the system ensures that the synthetic images more accurately represent real-world examination outputs of a specific examination tool. These synthetic images can be applied to various applications, including defect detection and tool matching.

### TECHNICAL FIELD

The presently disclosed subject matter is related to examination of semiconductor specimens.

### BACKGROUND

As semiconductor processes advance, critical dimensions such as line width and other pattern features are continuously reduced, necessitating precise control and uniformity in device structures. This requires continuous monitoring and examination of semiconductor specimens during fabrication to ensure that process parameters are met.

Traditionally, semiconductor examination for verifying the accuracy of fabricated features and identifying deviations from desired specifications relies on technologies such as optical microscopy, electron microscopy, and other automated systems to enhance accuracy. For instance, scanning Electron Microscopes (SEM) are widely used for high-resolution imaging in semiconductor metrology.

### GENERAL DESCRIPTION

While SEM imaging provides highly detailed and precise images critical for various applications in the industry, it may still be time-consuming and costly due to the physical scanning required.

To improve efficiency, machine learning (ML) models have been utilized to generate artificial examination output images from CAD (Computer-Aided Design) data, enabling the simulation of examinations tools imaging without the need for actual scans. In case of SEM, these techniques allow manufacturers to predict how structures will appear under SEM. By integrating these synthetic images into the semiconductor examination workflow, various advantages can be achieved, such as earlier detection of potential issues, reduced reliance on physical examination tools, reduced costs, and improved overall process control and productivity.

According to a first aspect of the presently disclosed subject matter there is provided a computer-implemented method of generating synthetic examination output images of a semiconductor specimen, the method comprising:
obtaining CAD data of a semiconductor specimen;
applying the CAD data and tool-specific priors of a semiconductor examination tool, to a machine learning (ML) model trained to generate synthetic examination output images;
wherein the tool-specific priors are indicative of operational parameters specific to the semiconductor examination tool and wherein the ML model is trained using CAD data and real examination output images generated by the semiconductor examination tool, and one or more respective priors used during the generation of the real examination output images, to thereby train the model to generate synthetic examination output images that simulate variations resulting from operational parameters of the examination tool; and
generating synthetic examination output images that simulate how the semiconductor examination tool would capture the semiconductor specimen given the tool-specific priors.

In addition to the above features, the method according to this aspect of the presently disclosed subject matter can optionally comprise one or more of features (i) to (viii) below, in any technically possible and technically possible combination or permutation:
i. Wherein the semiconductor examination tool is a scanning electron microscope (SEM), and the synthetic examination output images are synthetic SEM images generated by simulating how the SEM would capture the semiconductor specimen given the priors.
ii. Wherein the tool-specific priors comprise knob parameters of the examination tool.
iii. Wherein the knob parameters include one or more of: accelerating voltage, beam current, working distance, spot size, and scanning speed.
iv. Wherein the tool-specific priors comprise a resolution target image, representing the expected quality or precision of the examination tool output, and is used to simulate tool-specific variations in the generated synthetic examination output images.
v. Wherein the examination tool is an optical examination tool, and the synthetic examination output images are synthetic images generated by simulating how the optical examination tool would capture the semiconductor specimen given the priors.
vi. Wherein the tool-specific priors of the examination tool include tool-specific priors of two or more metrology tools; the method further comprising executing a metrology tools matching process comprising:
   for each of the two or more metrology tools:
   applying the CAD data of the semiconductor specimen and respective tool-specific priors to the machine learning model to obtain respective synthetic tool-specific examination output images that reflect variations resulting from the operational parameters applied to the metrology tool;
   comparing metrology measurements between synthetic tool-specific examination output images of different metrology tools of the two or more metrology tools; and upon identification of variations between the metrology measurements updating at least one metrology recipe of at least one of the two or more metrology tools, thereby allowing for matching of different metrology tools.
vii. Wherein the tool-specific priors of the examination tool include multiple tool-specific priors, the method further comprising executing a defect detection process for detecting defects in a semiconductor specimen, the process comprising:
   applying the CAD data of the semiconductor specimen and multiple tool-specific priors to the machine learning model to generate synthetic tool-specific examination output images, wherein the synthetic tool-specific examination output images generated using different tool-specific priors exhibit variations reflecting differences in operational parameters applied to respective semiconductor examination tools; and
   using a second machine learning model dedicated to detecting defects in examination output images, wherein the second machine learning model is trained on training data comprising the synthetic examination output images and faulty SEM images containing defects, thereby enabling the second machine learning model to distinguish between defects in the semiconductor specimen and variations resulting from differences in operational parameters of the examination tool configurations.
viii. The method further comprising executing feature measurements process using a machine learning model, the process comprising:
   applying the CAD data of the semiconductor specimen and multiple tool-specific priors to the machine learning model to generate synthetic tool-specific examination output images, wherein the synthetic tool-specific examination output images generated using different tool-specific priors exhibit variations reflecting differences in operational parameters applied to respective semiconductor examination tools; and
   using a second machine learning model dedicated to metrology measurements in examination output images, wherein the second machine learning model is trained on training data comprising the synthetic examination output images labeled with information indicative of dimension values of features therein, thereby enabling the second machine learning model to accurately determine feature measurements notwithstanding variations resulting from differences in operational parameters of the examination tool configurations.

According to a second aspect of the presently disclosed subject matter there is provided a computer system comprising a processing circuitry configured to execute the method of the first aspect above.

According to a third aspect of the presently disclosed subject matter there is provided a non-transitory computer readable medium comprising instructions that, when executed by a computer, cause the computer to perform a method according to the first aspect above.

According to a fourth aspect of the presently disclosed subject matter there is provided a computer program product comprising a non-transitory computer-readable medium having computer-executable instructions stored thereon, which, when executed by a processor, cause the processor to execute a method according to the first aspect above.

The methods, the systems, and the non-transitory program storage devices, disclosed with reference to the second, third and fourth aspects, can optionally comprise one or more of features (i) to (viii) listed above, mutatis mutandis, in any technically possible combination or permutation.

According to a fifth aspect of the presently disclosed subject matter there is provided a computer-implemented method of executing defect detection in a semiconductor specimen, comprising:
using a machine learning (ML) model dedicated to detecting defects in examination output images of the semiconductor specimen, wherein the machine learning model is trained on training data comprising synthetic examination output images and faulty SEM images containing defects;
wherein the synthetic examination output images are generated by applying CAD data of a semiconductor specimen and multiple tool-specific priors of a semiconductor examination tool, to a second ML model trained to generate the synthetic examination output images;
wherein the second ML model is trained to generate different synthetic tool-specific examination output images according to different tool-specific priors that exhibit variations reflecting differences in operational parameters applied to respective semiconductor examination tools;
wherein training the ML model with the training data enables it to distinguish between defects in the semiconductor specimen and variations resulting from differences in operational parameters of the examination tool configurations.

According to a fifth aspect of the presently disclosed subject matter there is provided a computer-implemented method of feature measurements in a semiconductor specimen, comprising:
using a machine learning (ML) model dedicated to measuring features in examination output images of the semiconductor specimen, wherein the machine learning model is trained on training data comprising synthetic tool-specific examination output images generated by a synthetic generation feature measurement ML model;
wherein the synthetic tool-specific examination output images are generated by applying CAD data of the semiconductor specimen and multiple tool-specific priors of a semiconductor examination tool to the second ML model, wherein the synthetic generation ML model is trained to generate synthetic tool-specific examination output images;
wherein the synthetic generation ML model is trained to generate different synthetic tool-specific examination output images according to different tool-specific priors that exhibit variations reflecting differences in operational parameters applied to respective semiconductor examination tools;
wherein training the ML model with the training data enables it to better determine feature measurements notwithstanding variations resulting from differences in operational parameters of the examination tool configurations.

The presently disclosed subject matter further contemplates a computer system configured to execute the method according to the fifth or sixth aspect and a non-transitory computer readable medium comprising instructions that, when executed by a computer, cause the computer to perform a method according to the fifth and/or sixth aspects above.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1 shows a block diagram schematically illustrating a computer system, in accordance with certain examples of the presently disclosed subject matter;

FIG. 2 is a flowchart of operations carried out as part of training and execution of CAD-TO-Ex-IMAGE machine learning model, in accordance with certain examples of the presently disclosed subject matter;

FIG. 3 is a flowchart of operations carried out during a virtual metrology tools matching process, in accordance with certain examples of the presently disclosed subject matter; and

FIG. 4 is a flowchart of operations carried out during a tool-agnostic defect learning and detection process, in accordance with certain examples of the presently disclosed subject matter.

### DETAILED DESCRIPTION

A wafer is a thin, typically circular slice of semiconductor material, often silicon, that serves as a substrate for manufacturing integrated circuits. A semiconductor die is an independent and discrete component of an integrated circuit, such as an individual computer processor. Each die contains a specific set of electronic components, all fabricated together on the same wafer. Generally, during the fabrication process, multiple dies are created on a single wafer, each being a copy of the same integrated circuit design, effectively yielding identical copies of the integrated circuit.

The process of semiconductor fabrication involves multiple sequential processing steps or layers, each of which can introduce errors that may lead to yield loss. Examples of these steps include lithography, etching, deposition, planarization, growth (such as epitaxial growth), and implantation. Semiconductor examination, including metrology—the science of measurement—and defect detection, is critical to ensuring the accuracy and precision of these processes. Metrology focuses on measuring critical dimensions, such as line widths and layer thicknesses, to ensure that features are fabricated according to design specifications, while defect detection identifies any anomalies that may affect performance.

Various examination operations are performed at different processing steps or layers during the fabrication process to monitor and control quality. These operations may be repeated multiple times, for example after certain key processing steps or layers, to ensure that the fabrication process remains within specified tolerances and that any deviations or defects are promptly identified and addressed.

As mentioned above, machine learning models can be utilized to generate synthetic examination output images from CAD data, enabling the simulation of examination output images without the need for actual scans. These models are trained to correlate CAD data (representing an ideal design) with examination output images (reflecting real-world, post-fabrication structures). While CAD represents the desired theoretical model, real fabrication often introduces deviations from this ideal, such as variations in line width or surface imperfections. Considering SEM as an example, the machine learning model, trained on actual SEM images, learns how these deviations manifest in SEM images. Given a certain CAD design, the model can simulate the predicted deviations in the SEM output, providing a more accurate representation of how the fabricated structure will appear.

It is further disclosed that optical semiconductor examination tools can similarly leverage machine learning to generate synthetic images that predict deviations in optical properties, such as reflectivity and transmission. By training CAD data and real optical imaging output, these models can simulate interactions between the fabricated structure and light, allowing for the identification of potential issues before actual measurements are taken.

By simulating these fabrication imperfections, the ML model allows manufacturers to predict how real-world structures may differ from their intended design. This predictive capability enhances metrology and defect detection by offering a realistic preview of the final product, helping identify potential issues early in the process. This approach improves process control, reduces defects, and ensures that final products better meet design specifications.

While the use of machine learning models to generate synthetic examination output images offers various benefits, achieving accurate results depends significantly on the specific working parameters of the examination tool used during scanning. In SEM machines for example, factors such as beam voltage, aperture size, working distance, and magnification can all affect the quality and characteristics of the SEM image. Without accounting for these parameters during training and execution of the model, the synthetic examination output images generated by the model may not accurately reflect the real-world output of the respective examination tool it intends to simulate.

To address this challenge, the presently disclosed subject matter includes a tool-specific machine learning model trained to receive input data comprising both CAD data and priors.

In this context, according to one example, “prior knowledge” or “priors” refers to the specific combination of operational parameters of a certain semiconductor examination tool. In the context of SEM tools, examples of priors include knob parameters or settings, such as accelerating voltage (which controls the electron beam's energy), beam current, working distance (influencing resolution and depth of field), spot size, and scanning speed (affecting image quality and acquisition time). These settings introduce variations in SEM output images based on the specific configurations applied.

Alternatively, SEM resolution target images can serve as priors, directly correlating with the SEM operating parameters. SEM resolution target images refer to calibrated images or patterns used to assess and verify the resolution capabilities of a SEM tool, ensuring that the instrument can accurately distinguish fine details in the sample being examined. In this case, the resolution of the target defines the expected image quality, and the model is trained to associate specific variations in output images with these resolution target images rather than directly relaying on the individual operating settings.

Another example of priors is an SEM image of a real semiconductor specimen captured by a specific SEM tool. This image reflects the tool's imaging characteristics, such as resolution and noise, and can be used as a reference to describe the tool's current imaging state, reflecting how the tool performs in terms of its imaging quality and performance under specific conditions.

For optical semiconductor examination tools, priors can include tool-specific settings such as light source wavelength, angle of incidence, polarization state, and detector sensitivity, all of which influence the measurement outputs. Additional priors may consist of optical images from different locations captured by the same tool, offering contextual information about variations in measurement results across different regions. These priors enable the machine learning model to accurately simulate the optical tool's behavior under varying conditions.

By incorporating priors alongside CAD data and corresponding examination output images as ground truth in the training dataset, the machine learning model learns to associate image variations with specific priors. During inference, priors can be applied alongside the CAD input to generate synthetic examination output images that reflect the unique operational parameters defined by those priors. This flexibility to adjust operational parameters based on the priors during inference enables the creation of tool-specific synthetic images that closely replicate real examination outputs across various configurations. By accurately mirroring real-world examination tool conditions, this approach enhances precision in metrology and defect detection, supporting more reliable analysis and predictions.

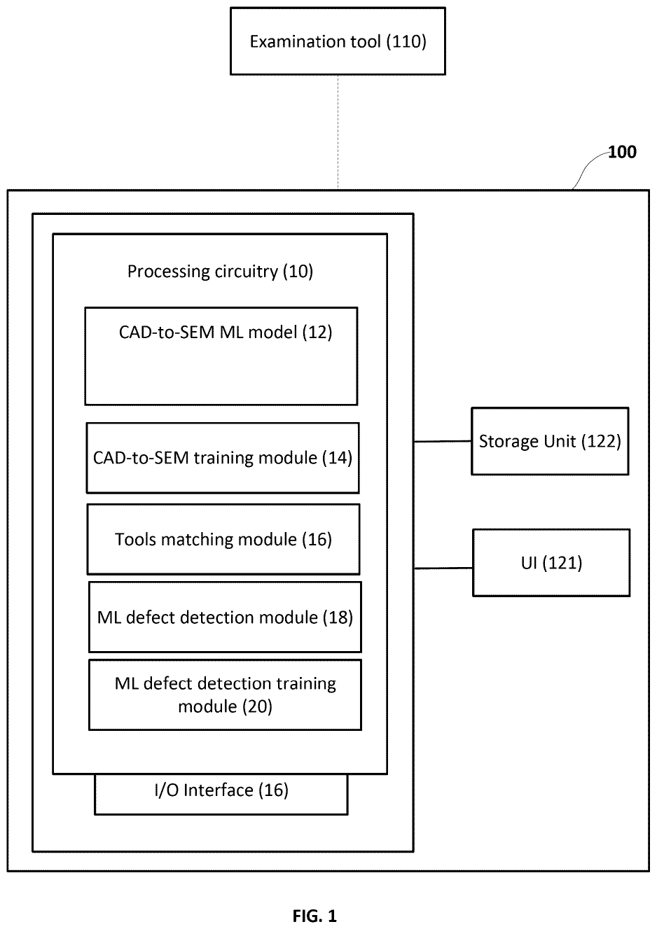

Bearing the above in mind, attention is drawn to FIG. 1, which is a generalized block diagram illustration of a computer system 100 configured with tool-specific machine learning capabilities according to examples of the presently disclosed subject matter.

It is noted that while the following description focuses on SEM examination tools, this is done by way of example only. The focus on SEM tools is illustrative, and the described methods and concepts are applicable to a range of examination tools, including those utilizing optical techniques.

Computer system 100 is configured and operable to generate synthetic examination output images using a tool-specific machine learning model. In some examples, system 100 can be used for examination of a semiconductor specimen (e.g., a wafer, a die, or parts thereof) e.g., as part of the specimen fabrication process. The examination referred to herein can be construed to include any kind of operations related to inspection of semiconductor specimens, including the inspection/detection of defects, defect classification, segmentation, metrology operations, etc., with respect to the specimen. Optionally, system 100 can comprise, be integrated within, or be otherwise operatively connected to one or more examination tools.

The term “examination tool” as used herein should be broadly interpreted to cover various tools used in examination-related processes of a semiconductor specimen. Examination tools include, for example, various focused charged particle beam devices (FCPB) that can be used in examination-related processes. FCPB tools include, for example, Scanning Electron Microscopes (SEM), Transmission Electron Microscopes (TEM), Focused Ion Beam (FIB) systems, and Scanning Transmission Electron Microscopes (sTEM). Additionally, examination tools encompass optical devices, such as optical microscopes, which are used for imaging, and tools like ellipsometers and reflectometers, which are used to measure film thickness and optical properties such as refractive index and reflectivity in semiconductor specimens. Images generated by an examination tool are also referred to herein as “examination output images”.

As mentioned above, one example of an examination tool is a Scanning Electron Microscope (SEM), which can be used for inspection and/or review. A SEM is a type of electron microscope that produces grayscale images of a specimen by scanning it with a focused beam of electrons. The operation of a SEM involves directing a focused beam of high-energy electrons toward a sample surface. This electron beam is generated by an electron gun and is then precisely focused and directed using electromagnetic lenses. As the electron beam scans across the surface of the sample, it interacts with the atoms, leading to various outcomes such as the emission of secondary electrons, backscattered electrons, and characteristic X-rays.

The detection of secondary electrons (emitted from atoms near the surface) allows for high-resolution imaging of the sample's topography. Backscattered electrons, which are the primary electrons electromagnetically deviated from the sample atoms, provide information on the composition and contrast, based on the atomic number differences within the sample.

Detectors designed for specific types of emissions capture the signals resulting from these interactions. This collected data is then processed to produce a grayscale image, indicating the quantity of electrons captured by the detector. This number of collected electrons varies, depending on the surface topography, composition, or other properties of the sample. Through this process, SEM tools can generate highly detailed grayscale images of the sample surface at magnification levels unattainable with traditional optical microscopes, providing precise inspection and measurement capabilities during the manufacturing of semiconductor wafers.

Examination tools include both inspection and review tools, each serving a distinct role in the semiconductor analysis process. The inspection phase involves scanning the entire wafer surface to quickly identify potential defects or anomalies across a broad area. This phase prioritizes speed and coverage, enabling the identification of areas that may require further examination.

The review phase, on the other hand, focuses on detailed analysis of specific areas flagged during the inspection phase. This phase involves a more thorough, in-depth examination of smaller regions to closely assess and characterize any identified defects. While inspection provides a broad overview, review ensures precision and accuracy in analyzing critical features, ensuring comprehensive evaluation of the wafer.

The inspection tool and review tool can be different tools located at the same or at different locations, or a single tool operated in two different modes. In some cases, the same examination tool can provide low-resolution image data and high-resolution image data.

Per the illustrated example, computer system 100 comprises processing circuitry 10 that is configured to execute various processing operations, as further described below. Processing circuitry 10 can comprise one or more processors and one or more memories (not shown). In some examples, the processing circuitry is configured to execute several functional modules based on computer-readable instructions stored in a non-transitory computer-readable memory included in the processing circuitry. These functional modules are hereinafter referred to as being comprised in the processing circuitry.

The functional modules include a module dedicated for generating synthetic examination output images emulating real examination output images of an examination tool. In some examples, the functional modules also include a CAD-TO-SEM training module 14 that is configured to train the CAD-TO-SEM ML model. Notably, in other examples, system 100 can include alternative or additional modules dedicated to executing machine learning models configured to generate synthetic examination output images of other types of examination tools. Such models can be referred to collectively as a “CAD-TO-Ex-IMAGE” ML models. This broad term encompasses machine learning models that generate synthetic examination output images based on CAD data, applicable to tools such as SEM, optical microscopes, and other examination tools used for semiconductor examination.

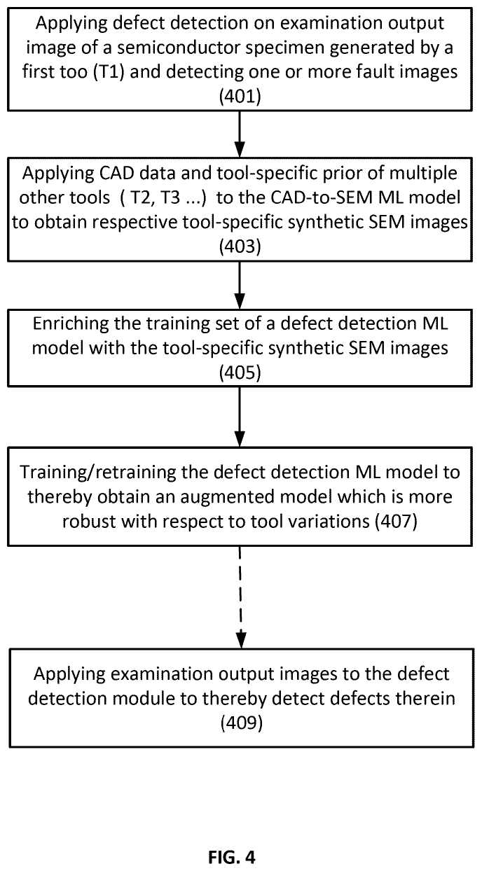

In addition, the functional modules can, in some examples, further include one or more of an examination tools matching module 16 that is configured to execute a metrology tools matching process using synthetic tool-specific examination output images (and is thus referred to as a “virtual metrology tools matching process”), and a tool-agnostic defect detection ML module 18 that is configured to apply a machine learning model trained to detect defects in SEM images with reduced effect from the specific tool that generated the image on the detection process. Specific operations related to these modules are described below with reference to FIGS. 4 to 5. Notably, although FIG. 1 depicts both the training module 14 and the model 12 as integrated components of system 100, in some implementations system 100 may not perform the training process itself. Instead, the training may be conducted externally, and system 100 receives the model after it has been trained in an independent environment.

According to some examples, system 100 can comprise or be otherwise operatively connected to a data-storage unit 122 configured to store any data necessary for operating system 100. This includes for example computer software which is loaded during execution of any one of the modules described above, intermediate processing results generated by system 100, tool-specific priors, synthetic examination output images, etc.

In some examples, system 100 can optionally comprise a user interface 121 to enable user interaction with system 100. The user interface can include a display device, user interaction devices (e.g., computer mouse and keyboard) and a graphical user interface (GUI) configured to enable, inter alia, user-specified inputs related to system 100. For instance, the user may view on the display the processing results or intermediate processing results, such as, e.g., synthetic SEM images, outputs of the tool matching module 16, outputs of ML detection module 18, etc.

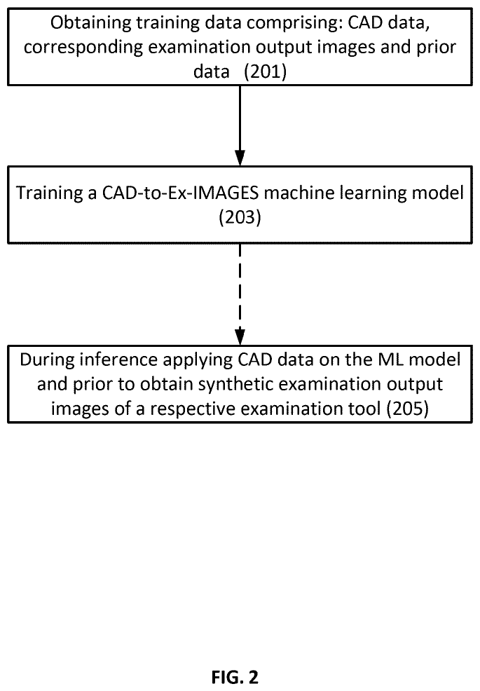

Turning to FIG. 2, it shows operations carried out as part of training and execution of the CAD-TO-Ex-IMAGE machine learning model, according to examples of the presently disclosed subject matter. It is noted that while operations in FIGS. 2, 3, and 4 are described with reference to various components in FIG. 1, this is done by way of example only and should not be construed as limiting the processes to the specific system design illustrated in any of these figures.

A training dataset comprising data for training the CAD-TO-Ex-IMAGE machine learning (ML) model is obtained (201). The purpose of this training is to develop a machine learning model that takes CAD data and “priors” as input, and generates corresponding synthetic examination output images of an examination tool that accurately reflect variations based on the priors. In the example of a SEM, the training dataset includes examples of CAD designs of semiconductor specimens, along with the corresponding SEM images (otherwise referred to herein as “real SEM examination output images”) generated using different tool-specific priors, and the respective priors. Different priors represent various operational parameter settings of the SEM tools (otherwise known as “knob parameters”). By incorporating multiple priors and their corresponding SEM images in the training dataset, the CAD-TO-SEM model is trained to learn the variations in the images that result from different tool configurations. This enables the model to understand and accurately simulate the effects of these priors on the resulting SEM images. Training datasets can be stored and made available for training in a computer data-storage operatively connected to system 100, e.g., storage unit 122.

The training dataset is used for training the machine learning model (203). During training, the model is taught to map the relationships between the input CAD data, priors, and the resulting SEM examination output images. The ground truth refers to the actual SEM images generated by the SEM tool, which serve as the reference for the model's learning process. The model is trained to generate synthetic examination output images that exhibit variations according to the priors provided. In case of a SEM, where synthetic SEM images are generated, this means the model learns to associate different priors settings with corresponding changes in the real SEM examination output images, allowing it to simulate how various knob parameters affect the final output. By minimizing the difference between the synthetic images and the ground truth, the model is optimized to produce accurate, realistic synthetic SEM images under different knob parameters. Training can be executed, for example, by CAD-to-SEM training module 14. The trained model can be stored on a computer storage device being operatively connected to system 100.

Once the CAD-to-SEM model has been trained, it can be used to generate synthetic SEM images (205). During inference, new CAD data and corresponding priors are applied to the model. By applying priors that matches the settings of a specific SEM tool, the model can more accurately simulate SEM images generated by that particular SEM. This allows the model to adjust the synthetic output to closely reflect the real-world behavior of the specific SEM tool, ensuring that the generated images align with the tool's actual configurations and performance. The model can therefore be considered a tool-specific CAD-to-SEM model, as its outputs can be more accurately adapted to resemble the outputs of a particular SEM tool according to the specific knob parameters or resolution targets provided as priors. This leads to more reliable simulations, enabling enhanced precision in both metrology and defect detection tasks.

In some examples, a CAD-to-SEM model is implemented as a deep neural network (DNN). DNN can refer to a supervised or unsupervised DNN model which includes layers organized in accordance with respective DNN architecture. By way of non-limiting example, the layers of a DNN can be organized in accordance with Convolutional Neural Network (CNN) architecture, Recurrent Neural Network architecture, Recursive Neural Networks architecture, Generative Adversarial Network (GAN) architecture, or otherwise. Each layer of a DNN can include multiple basic computational elements (CE), typically referred to in the art as dimensions, neurons, or nodes.

Notably, the same principles described above can be likewise applied with other types of examination tools and respective examination output images. For example, in case of an optical examination tool, the ML model can be trained using optical examination output images and appropriate priors.

Once the CAD-to-SEM ML model is available, it can be used for generating synthetic examination output images that can be used in a variety of applications, including improving the accuracy and efficiency of SEM image analysis. The model can assist in tasks such as defect detection, metrology, and process optimization by generating synthetic SEM images that closely match real-world outputs. This allows operators to better understand and predict how different tool settings or conditions will affect the resulting images, thereby improving decision-making and overall performance during SEM image analysis.

Procedures leveraging tool-specific synthetic examination output images to enhance defect detection and metrology processes are disclosed herein. According to one example, the presently disclosed subject matter includes a computer system and a computer-implemented method for a virtual metrology tool-matching process. In metrology tasks, it is crucial to determine variations in measurements between different examination tools of the same type, to assess the accuracy, identify tool-dependent variations, and detect any deficiencies in the tools themselves. In the example of a SEM, this process typically involves scanning the same specimen with multiple SEM tools, generating corresponding images, and applying metrology to each image for comparison. However, this method is costly, time-consuming, and cumbersome, due to the need for repeated scans across various tools.

The CAD-TO-Ex-IMAGE mitigates these challenges by generating synthetic examination output images that simulate the outputs of different respective examination tools. In the example of a SEM, the CAD-TO-SEM model mitigates these challenges by generating synthetic SEM images that simulate the outputs of different SEM tools. Instead of conducting actual scans with multiple machines, the model produces images that simulate how each tool would capture the specimen. This allows for a comparison of tool-specific variations and potential deficiencies without requiring physical scans. The model thus not only helps in assessing measurement accuracy and identifying variations, but also assists in matching a fleet of metrological tools and diagnosing deficiencies in tool performance. This approach reduces cost, saves time, and streamlines metrology operations, providing a more efficient and scalable method for tool comparison and calibration than matching performed using actual scanning by different tools in the fleet.

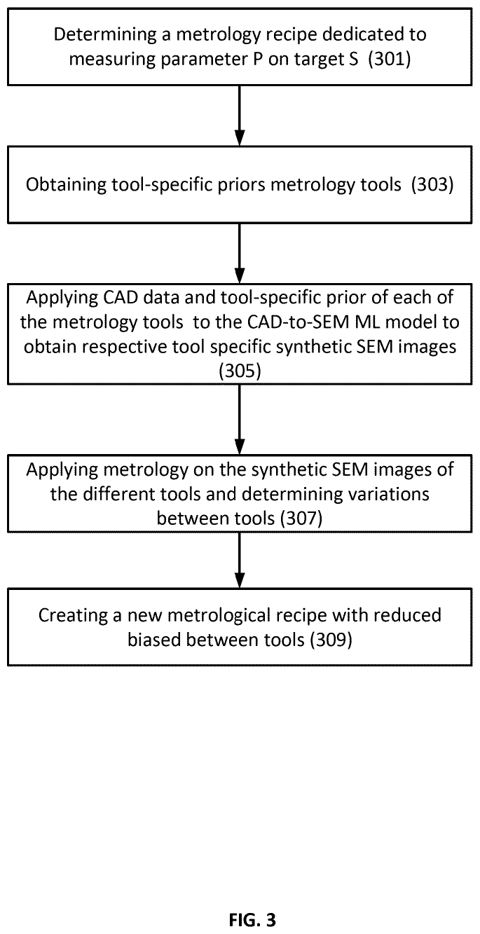

FIG. 3 shows an example of the sequence of operations carried out during this process. Operations described with reference to FIG. 3 can be optionally carried out by tools matching module 16.

Initially, a metrology recipe is created (301). A metrology recipe is a set of predefined instructions, parameters, and configurations used in a metrology tool (e.g., SEM) to perform consistent and accurate measurements of physical dimensions or characteristics of semiconductor specimens (e.g., a wafer, die, or part thereof). The recipe ensures repeatability and precision across multiple measurements and can be tailored to the specific task or material being measured.

Assuming it is desired to measure a parameter P (e.g., the width of a metal line) on a semiconductor specimen S (e.g., wafer), a metrology recipe would define the specific parameters and steps required to perform the measurement consistently and accurately.

Tool-specific priors of multiple metrology tools (T1 to Tn), which are to be matched, are obtained (303). In the example of SEM metrology tools, the priors can include specific settings or knob parameters unique to each SEM tool, such as accelerating voltage, beam current, working distance, or other knob parameters that affect the SEM's output. For example, one SEM metrology tools may use an accelerating voltage of 5 kV and a working distance of 10 mm, while another tool may operate at 15 kV with a working distance of 8 mm. These variations in tool parameters lead to differences in how features, including defects, are captured, imaged, and represented in the output, potentially affecting defect characterization and analysis.

For each tool, the same CAD data (representing the semiconductor specimen design) is applied along with its distinct tool-specific priors to the CAD-to-Ex-IMAGES ML model (305). In case of a SEM, the CAD-to-SEM ML model generates respective synthetic SEM images for each tool. These images simulate how each tool would scan and capture the same specimen. The images are characterized by the variations introduced by the model based on the tool-specific priors, reflecting the differences in tool configuration.

Although the model may have been trained using images generated by one tool, it can still provide accurate estimations of the output from other tools. This is because the ML model learns to generalize the relationship between tool-specific priors and image features, enabling it to effectively handle outputs from different tools.

Metrology is then applied to the generated synthetic SEM images of each tool. The results of these measurements are compared to identify variations between tools outputs (307). As mentioned above, this approach eliminates the need for physical scans with multiple tools, saving both time and cost.

According to some examples, following the measurements an updated metrological recipe can be created (across all tools) to improve the consistency of measurements across different tools in the fleet (309). This can be achieved for example through modifying algorithm-related parameters. Algorithm-related modifications may involve adjustments to parameters that control image processing, measurement logic, and sensitivity settings. These changes affect how algorithms process images, detect features, and measure various critical dimensions, ultimately optimizing the system's accuracy, precision, and sensitivity.

In some examples one of the following approaches are used when determining modifications:

### Bias Learning and Adjustment:

In this approach, the bias between the metrology measurements of different tools is determined. A reference tool, such as T1, can be identified, and the results from other tools (T2, T3, etc.) are compared to the results of the reference tool. By analyzing the bias or deviation of each tool relative to the reference tool, the new metrology recipe of each tool is adjusted to account for these variations. This ensures that the measurements from all tools are aligned and consistent, improving the accuracy of the fleet's overall performance.

In some examples, the process can be repeated, with the updated recipes used each time to generate synthetic SEM images for comparison. This iteration continues until the differences between the outputs of different metrology tools fall within an acceptable range. Proceeding to FIG. 4, this shows a flowchart of operations carried out during a tool-agnostic defect learning process, in accordance with certain examples of the presently disclosed subject matter. In common training of ML (e.g., deep learning) defect detection models, the model is trained on a dataset of faulty images that includes images captured by a certain SEM tool. The model learns to recognize and detect defects based on these images, but its performance can be limited when applied to images captured by other tools, as it is often sensitive to tool-specific variations in imaging, such as differences in resolution, focus, or beam settings. These variations may be mistakenly interpreted as defects, leading to skewed detection results and reduced accuracy when the model is used across different tools.

The process illustrated in FIG. 4 addresses this limitation by incorporating the CAD-to-SEM model to generate synthetic fault images with defects that simulate variations between different SEM tools, making the defect detection model more robust. Operations described with reference to FIG. 4 can be performed for example by ML defect detection training module 20.

Initially, a dataset of faulty images is collected from a single SEM tool (401). These defects may be detected using various existing methods, such as:
Manual inspection, where experts visually identify defects in SEM images.
Automated defect detection algorithms, which apply predefined rules or image processing techniques to detect defects.
Machine learning-based defect detection models, which have already been trained to identify defects. If an ML defect detection model is used, it can later be re-trained using the synthetic data generated in the next steps.

Next, the CAD-to-SEM model is employed to create synthetic SEM images for the training dataset (403). The CAD-to-SEM model generates synthetic SEM images of the same CAD designs, but with variations introduced by simulating different priors (e.g., tool-specific knob parameters). This allows for the creation of synthetic SEM images that reflect how the SEM images would appear if captured by other SEM tools, accounting for tool-induced variations.

The synthetic SEM images are then added to the original training set together with the faulty SEM images (405), creating a more diverse dataset that includes both images with real defects and synthetic SEM images that exhibit variations resulting from the added prior which are not defects. This enriched dataset helps the machine learning model or other algorithm being used to better distinguish between actual defects and tool-specific variations.

Finally, the deep learning model or any other applied defect detection algorithm is trained or re-trained on this expanded dataset (407). If a pre-existing ML model was used, it can now be re-trained with the augmented dataset to improve its robustness to tool-specific variations.

Once the model has been trained or re-trained, the augmented defect detection model can be applied to examination output images (409), which may be either synthetic or real SEM images. The model processes these images to automatically detect defects based on the diverse set of training data it has been exposed to. By leveraging the tools-specific knowledge gained from the augmented dataset, the model becomes capable of accurately identifying defects, even when applied to images from different SEM tools with varying configurations. This ensures that the model delivers consistent and reliable defect detection, regardless of the tool used to capture the images, effectively making the model agnostic to the specific SEM tool.

It is noted that while the processes in FIGS. 4 and 5 were described with reference to a SEM examination tool, this is done by way of example only. The same principles can likewise be applied to output images generated by other examination tools.

The presently disclosed subject matter further contemplates using the CAD-to-Ex-IMAGES ML model to generate synthetic images for the training of a metrology machine learning model, enabling the creation of a more robust and accurate metrology model.

A machine learning model is trained to predict the measurement of certain features directly from SEM images (“metrology ML model”). In some examples, to train a machine learning model for metrology, a dataset consisting of images is collected, where each image is labeled with the correct measurement values for the features of interest (e.g., line width, height, or spacing). These ground truth measurements are typically obtained using traditional metrology techniques. The model is then trained to learn the relationship between the image data and the corresponding measurements, allowing it to predict accurate measurements directly from new images.

During training, the model learns to extract relevant features from the images that correlate with the target measurements. By minimizing the difference between the model's predictions and the ground truth values, the model can be fine-tuned to perform precise measurements. Once trained, the model can automate the metrology process, offering consistent and reliable measurements across a range of images without requiring manual analysis.

According to the disclosed approach, synthetic SEM images generated by the CAD-to-SEM model are used for training the metrology ML model instead of or in addition to real SEM images. These synthetic images are created based on the same CAD data and different priors to simulate the variations introduced by different SEM tool knob parameters. This provides the metrology ML model with a diverse set of examples that exhibit variations resulting from different operational parameters used by the respective tool, making it more robust to real-world variations in SEM tool configurations. As a result, during inference the model can generate accurate and consistent metrology measurements (e.g., critical dimensions measurements) across different conditions without being dependent on specific tool configurations. The ground truth for these synthetic images is derived from actual metrology measurements, ensuring that the model is robustly trained on reliable data for precise prediction.

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified, and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

While certain examples of the present disclosure refer to a processing circuitry being configured to perform the above recited operations, the functionalities/operations of the aforementioned functional modules can be performed by the one or more processors in the processing circuitry in various ways. By way of example, the operations of each module can be performed by a specific processor, or by a combination of processors. The operations of the various functional modules, such as processing the examination/inspection image, and performing defect examination, etc., can thus be performed by respective processors (or processor combinations), while, optionally, these operations may be performed by the same processor. The present disclosure should not be limited to being construed as one single processor always performing all the operations. Furthermore, any reference made in the specification and claims to a single processing circuitry should be interpreted to optionally include multiple processing circuitries.

The systems illustrated in FIG. 1 can be implemented in a distributed computing environment, in which one or more of the aforementioned components and functional modules shown in FIG. 1 can be distributed over several local and/or remote devices. By way of example, the examination tool 120 and systems 100 can be located at the same entity (in some cases hosted by the same device) or distributed over different entities, each located at a different location. likewise, the training modules 14 and 20, illustrated as part of system 100, could be executed by another computer system, with the trained model then provided to system 100 to facilitate execution. Furthermore, while FIG. 1 shows modules 16, 18, and 20 as part of system 100, this is for illustrative purposes only, as any of these modules may not necessarily be implemented as part of system 100 in actual practice.

In some examples, certain components utilize a cloud implementation, e.g., implemented in a private or public cloud. Communication between the various components of the examination system, in cases where they are not located entirely in one location or in one physical entity, can be realized by any signaling system or communication components, modules, protocols, software languages and drive signals, and can be wired and/or wireless, as appropriate.

Unless specifically stated otherwise, as apparent from the above discussions, it is appreciated that, throughout the specification, discussions utilizing terms such as “obtaining”, “generating”, “applying”, “executing”, “using”, or the like, include an action and/or processes of a computer that manipulate and/or transform data into other data, said data represented as physical quantities, e.g. such as electronic quantities, and/or said data representing the physical objects.

The terms “computer”, “computer system”, “computer device”, “computerized device”, “computerized system” or the like used herein, should be expansively construed to include any kind of hardware-based electronic device with one or more data processing circuitries. Each processing circuitry can comprise, for example, one or more processors operatively connected to computer memory, capable of executing stored instructions to perform the operations described herein.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a graphics processing unit (GPU), a network processor, or the like.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately, or in any suitable sub-combination.

In various examples of the presently disclosed subject matter, fewer, more and/or different stages than those shown in FIGS. 2 to 4, may be executed. In some examples one or more stages illustrated in the figures may be executed in a different order, and/or one or more groups of stages may be executed simultaneously.

It will also be understood that the system according to the presently disclosed subject matter may be a suitably programmed computer. Likewise, the presently disclosed subject matter contemplates a computer program being readable by a computer for executing the method of the presently disclosed subject matter. The presently disclosed subject matter further contemplates a machine-readable (e.g., non-transitory) memory tangibly embodying a program of instructions executable by the machine for executing the method of the presently disclosed subject matter.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A computer system configured for generating synthetic examination output images of a semiconductor specimen, the computer system comprising a processing circuitry configured to:
obtain CAD data of a semiconductor specimen;
apply the CAD data and tool-specific priors of a semiconductor examination tool, to a machine learning (ML) model trained to generate synthetic examination output images;
wherein the tool-specific priors are indicative of operational parameters specific to the semiconductor examination tool and wherein the ML model is trained using CAD data and real examination output images generated by the semiconductor examination tool, and one or more respective priors used during the generation of the real examination output images, to thereby train the model to generate synthetic examination output images that simulate variations resulting from operational parameters of the examination tool; and
generate synthetic examination output images that simulate how the semiconductor examination tool would capture the semiconductor specimen given the tool-specific priors.

2. The computer system of claim 1, wherein the examination tool is a scanning electron microscope (SEM), and the synthetic examination output images are synthetic SEM images generated by simulating how the SEM would capture the semiconductor specimen given the priors.

3. The computer system of claim 1, wherein the tool-specific priors comprises knob parameters of the examination tool.

4. The computer system of claim 3, wherein the knob parameters include one or more of: accelerating voltage, beam current, working distance, spot size, and scanning speed.

5. The computer system of claim 1 wherein the tool-specific priors comprise a resolution target image, representing the expected quality or precision of the examination tool output, and is used to simulate tool-specific variations in the generated synthetic examination output images.

6. The computer system of claim 1, wherein the examination tool is an optical examination tool, and the synthetic examination output images are synthetic images generated by simulating how the optical examination tool would capture the semiconductor specimen given the priors.

7. The computer system of claim 1, wherein the tool-specific priors of the examination tool include tool-specific priors of two or more metrology tools and wherein the processing circuitry is configured to execute a metrology tools matching process comprising:
for each of the two or more metrology tools:
applying the CAD data of the semiconductor specimen and respective tool-specific priors to the machine learning model to obtain respective synthetic tool-specific examination output images that reflect variations resulting from the operational parameters applied to the metrology tool;
comparing metrology measurements between synthetic tool-specific examination output images of different metrology tools of the two or more metrology tools; and upon identification of variations between the metrology measurements updating at least one metrology recipe of at least one of the two or more metrology tools, thereby allowing for matching of different metrology tools.

8. The computer system of claim 1, wherein the tool-specific priors of the examination tool include multiple tool-specific priors and wherein the processing circuitry is further configured to execute a defect detection process for detecting defects in a semiconductor specimen, the process comprising:
applying the CAD data of the semiconductor specimen and multiple tool-specific priors to the machine learning model to generate synthetic tool-specific examination output images, wherein different synthetic tool-specific examination output images generated using different tool-specific priors exhibit variations reflecting differences in operational parameters applied to respective semiconductor examination tools; and
using a second machine learning model dedicated to detecting defects in examination output images, wherein the second machine learning model is trained on training data comprising the synthetic examination output images and faulty SEM images containing defects, thereby enabling the second machine learning model to distinguish between defects in the semiconductor specimen and variations resulting from differences in operational parameters of the examination tool configurations.

9. The computer system of claim 1, wherein the processing circuitry is further configured to execute a metrology machine learning model dedicated to providing feature measurements in a semiconductor specimen, the process comprising:
applying the CAD data of the semiconductor specimen and multiple tool-specific priors to the machine learning model to generate synthetic tool-specific examination output images, wherein the synthetic tool-specific examination output images generated using different tool-specific priors exhibit variations reflecting differences in operational parameters applied to respective semiconductor examination tools; and
using a second machine learning model dedicated to metrology measurements in examination output images, wherein the second machine learning model is trained on training data comprising the synthetic examination output images labeled with information indicative of dimension values of features therein, thereby enabling the second machine learning model to accurately determine feature measurements notwithstanding variations resulting from differences in operational parameters of the examination tool configurations.

10. A computer-implemented method of generating synthetic examination output images of a semiconductor specimen, the method comprising:
obtaining CAD data of a semiconductor specimen;
applying the CAD data and tool-specific priors of a semiconductor examination tool, to a machine learning (ML) model trained to generate synthetic examination output images;
wherein the tool-specific priors are indicative of operational parameters specific to the semiconductor examination tool and wherein the ML model is trained using CAD data and real examination output images generated by the semiconductor examination tool, and one or more respective priors used during the generation of the real examination output images, to thereby train the model to generate synthetic examination output images that simulate variations resulting from operational parameters of the examination tool; and
generating synthetic examination output images that simulate how the semiconductor examination tool would capture the semiconductor specimen given the tool-specific priors.

11. The method of claim 10, wherein the semiconductor examination tool is a scanning electron microscope (SEM), and the synthetic examination output images are synthetic SEM images generated by simulating how the SEM would capture the semiconductor specimen given the priors.

12. The method of claim 10, wherein the tool-specific priors comprise knob parameters of the examination tool.

13. The method of claim 12, wherein the knob parameters include one or more of: accelerating voltage, beam current, working distance, spot size, and scanning speed.

14. The method of claim 10, wherein the tool-specific priors comprise a resolution target image, representing the expected quality or precision of the examination tool output, and is used to simulate tool-specific variations in the generated synthetic examination output images.

15. The method of claim 10, wherein the examination tool is an optical examination tool, and the synthetic examination output images are synthetic images generated by simulating how the optical examination tool would capture the semiconductor specimen given the priors.

16. The method of claim 10, wherein the tool-specific priors of the examination tool include tool-specific priors of two or more metrology tools; the method further comprising executing a metrology tools matching process comprising:
for each of the two or more metrology tools:
applying the CAD data of the semiconductor specimen and respective tool-specific priors to the machine learning model to obtain respective synthetic tool-specific examination output images that reflect variations resulting from the operational parameters applied to the metrology tool;
comparing metrology measurements between synthetic tool-specific examination output images of different metrology tools of the two or more metrology tools; and upon identification of variations between the metrology measurements updating at least one metrology recipe of at least one of the two or more metrology tools, thereby allowing for matching of different metrology tools.

17. The method of claim 10, wherein the tool-specific priors of the examination tool include multiple tool-specific priors, the method further comprising executing a defect detection process for detecting defects in a semiconductor specimen, the process comprising:
applying the CAD data of the semiconductor specimen and multiple tool-specific priors to the machine learning model to generate synthetic tool-specific examination output images, wherein the synthetic tool-specific examination output images generated using different tool-specific priors exhibit variations reflecting differences in operational parameters applied to respective semiconductor examination tools; and
using a second machine learning model dedicated to detecting defects in examination output images, wherein the second machine learning model is trained on training data comprising the synthetic examination output images and faulty SEM images containing defects, thereby enabling the second machine learning model to distinguish between defects in the semiconductor specimen and variations resulting from differences in operational parameters of the examination tool configurations.

18. The method of claim 10 further comprising executing feature measurements process using a machine learning model, the process comprising:
applying the CAD data of the semiconductor specimen and multiple tool-specific priors to the machine learning model to generate synthetic tool-specific examination output images, wherein the synthetic tool-specific examination output images generated using different tool-specific priors exhibit variations reflecting differences in operational parameters applied to respective semiconductor examination tools; and
using a second machine learning model dedicated to metrology measurements in examination output images, wherein the second machine learning model is trained on training data comprising the synthetic examination output images labeled with information indicative of dimension values of features therein, thereby enabling the second machine learning model to accurately determine feature measurements notwithstanding variations resulting from differences in operational parameters of the examination tool configurations.

19. A computer program product comprising a non-transitory computer-readable medium having computer-executable instructions stored thereon, which, when executed by a processor, cause the processor to execute a method of generating synthetic examination output images of a semiconductor specimen comprising:
obtaining CAD data of a semiconductor specimen;
applying the CAD data and tool-specific priors of a semiconductor examination tool, to a machine learning (ML) model trained to generate synthetic examination output images;
wherein the tool-specific priors are indicative of operational parameters specific to the semiconductor examination tool and wherein the ML model is trained using CAD data and real examination output images generated by the semiconductor examination tool, and one or more respective priors used during the generation of the real examination output images, to thereby train the model to generate synthetic examination output images that simulate variations resulting from operational parameters of the examination tool; and
generating synthetic examination output images that simulate how the semiconductor examination tool would capture the semiconductor specimen given the tool-specific priors.
